(19) United States
(12) Patent Application Publication
(10) Pub. No.: US 2025/0267809 A1
(43) Pub. Date: Aug. 21, 2025

(54) DISPLAY DEVICE

(71) Applicant: LG Display Co., Ltd., Seoul (KR)

(72) Inventors: ChangHyun SONG, Paju-si (KR); Seunghwan KIM, Paju-si (KR)

(73) Assignee: LG Display Co., Ltd., Seoul (KR)

(21) Appl. No.: 18/793,516

(22) Filed: Aug. 2, 2024

(30) Foreign Application Priority Data
Feb. 21, 2024 (KR) 10-2024-0025185

(51) Int. Cl. H05K 5/02

(52) U.S. Cl. CPC H05K 5/0247

(57) ABSTRACT

A display device in one example includes a first connection part penetrating from an upper surface of the substrate to a lower surface of the substrate, and a second connection part protruding from the first connection portion to a side surface of the substrate. The second connection part is electrically connected with a driving unit. In addition, each of a plurality of lines is electrically connected with one of first and second driving units and is not electrically connected with the other one of the first and second driving units by a connection part.

### CROSS-REFERENCE TO RELATED APPLICATIONS

This application claims priority to Korean Patent Application No. 10-2024-0025185 filed in the Republic of Korea on Feb. 21, 2024, the entire contents of which is hereby expressly incorporated by reference into the present application.

### BACKGROUND

### Field

The present disclosure relates to a display device with improved light efficiency.

### Discussion of the Related Art

A display device is widely used as a display screen of a notebook computer, a tablet computer, a smart phone, a portable display device, and a portable information device in addition to a display screen of a television or a monitor. With the advancement of technology, the display device can provide photographing or various sensing functions in addition to an image display function. Accordingly, the display device can include an electronic device such as a camera or a sensor.

The display device can be a liquid crystal display device, a plasma display panel, an organic light-emitting display device, and the like.

The display device includes a display panel for displaying an image and a panel driver for driving the display panel. When the display panel and the panel driver are electrically connected with each other on an upper surface of the display panel, a bezel area of the display device can increase. Accordingly, in order to minimize the bezel area of the display device, research on a structure in which the display panel and the panel driver are electrically connected with each other on a side surface of the display panel has recently been conducted.

### SUMMARY OF THE DISCLOSURE

The present disclosure has been made in view of the above noted issues and needs associated with the related art, and it is an object of the present disclosure to provide a display device including a plurality of connection members disposed in a substrate.

In accordance with an aspect of the present disclosure, the above and other objects can be accomplished by the provision of a display device comprising a line disposed on an upper surface of a substrate, a driving unit disposed on a side surface of the substrate, and a connection part disposed in the substrate, wherein the connection part includes a first connection part penetrating from the upper surface of the substrate to a lower surface of the substrate, and a second connection part protruding from the first connection part to the side surface of the substrate, and the second connection part is in contact with the driving unit to be electrically connected with the driving unit at the side surface of the substrate.

In addition, in accordance with an aspect of the present disclosure, the above and other objects can be accomplished by the provision of a display device comprising a plurality of lines disposed on an upper surface of a substrate, a first driving unit disposed on a lower surface of the substrate, a second driving unit disposed on a side surface of the substrate, and a connection part disposed in the substrate, wherein each of the plurality of lines is electrically connected with one of the first and second driving units and is not electrically connected with the other by the connection part.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a perspective view of a display device according to a first embodiment of the present disclosure.

FIG. 2 is a plan view of the display device according to the first embodiment of the present disclosure.

FIG. 3 is a cross-sectional view of the display device according to the first embodiment of the present disclosure.

FIG. 4 is a cross-sectional view of a display device according to a second embodiment of the present disclosure.

FIG. 5 is a perspective view of a display device according to a third embodiment of the present disclosure.

FIG. 6 is a plan view of the display device according to the third embodiment of the present disclosure.

FIGS. 7 to 9 are cross-sectional views of the display device according to the third embodiment of the present disclosure.

FIGS. 10A to 10F are cross-sectional views illustrating a process of the display device according to the first and second embodiments of the present disclosure.

### DETAILED DESCRIPTION OF THE EMBODIMENTS

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

A shape, a size, a ratio, an angle and a number disclosed in the drawings for describing embodiments of the present disclosure are merely an example and thus, the present disclosure is not limited to the illustrated details. Like reference numerals refer to like elements throughout the disclosure. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion can be added unless ‘only’ is used. The terms of a singular form can include plural forms unless referred to the contrary.

In construing an element, the element is construed as including an error band although there is no explicit description.

In describing a position relationship, for example, when the position relationship is described as ‘upon’, ‘above’, ‘below’ and ‘next to’, one or more portions can be disposed between two other portions unless ‘just’ or ‘direct’ is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship.

Hereinafter, various embodiments of the present disclosure will be described in detail with reference to the accompanying drawings. All the components of each display device according to all embodiments of the present disclosure are operatively coupled and configured.

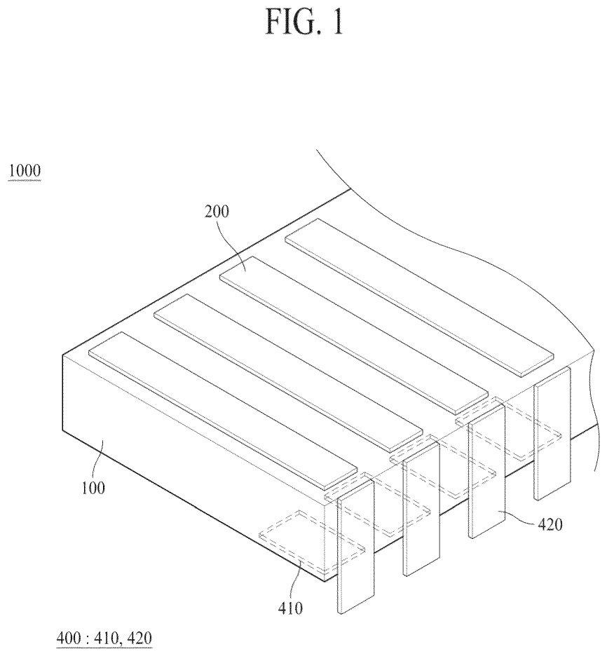

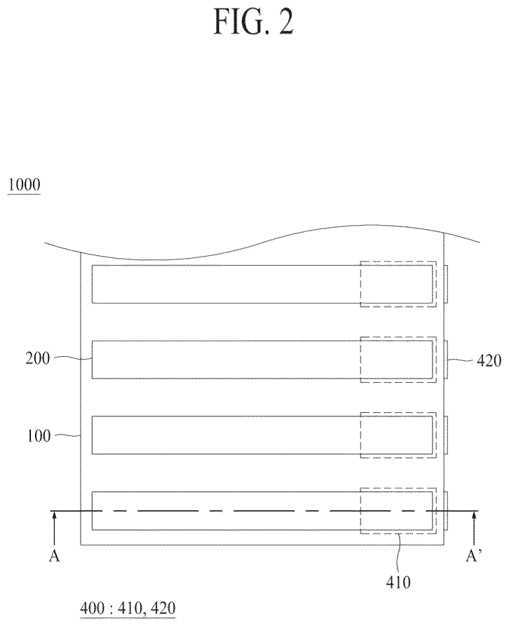

FIG. 1 is a perspective view of a display device 1000 according to a first embodiment of the present disclosure. Further, FIG. 2 is a plan view of the display device 1000 according to the first embodiment of the present disclosure. FIGS. 1 and 2 illustrate a partial area of the display device 1000.

Referring to FIGS. 1 and 2, the display device 1000 according to the first embodiment of the present disclosure can include a substrate 100, a plurality of lines 200, and a driving unit 400.

The substrate 100 can be made of glass or plastic, but is not limited thereto. The display device according to an embodiment of the present disclosure can be configured in a top emission type in which the emitted light is emitted upward. Therefore, as the material of the substrate 100, not only a transparent material but also an opaque material can be used.

The plurality of lines 200 can be disposed on an upper surface of the substrate 100. The plurality of lines 200 can be spaced apart from each other along one direction. Further, the plurality of lines 200 can be signal lines such as a gate line, a data line, or a common voltage line. In this case, the plurality of lines 200 can receive signals from the driving unit 400 and transfer signals to a driving element or a light emitting device.

The driving unit 400 is electrically connected with the plurality of lines 200, and can apply various signals to the plurality of lines 200. Further, the driving unit 400 can include a plurality of first driving units 410 and a plurality of second driving units 420.

The plurality of first driving units 410 can be disposed in an edge of a lower surface of the substrate 100. For example, the substrate 100 can be disposed between the plurality of lines 200 and the plurality of first driving units 410. The plurality of first driving units 410 can be spaced apart from each other in the same direction as the plurality of lines 200. Further, the plurality of first driving units 410 can be parallel to the plurality of lines 200. The plurality of first driving units 410 can overlap the plurality of lines 200. For example, the single first driving unit 410 can overlap the single line 200, but is not limited thereto. Further, an entire upper surface of the plurality of first driving units 410 can be in contact with the substrate 100, but are not limited thereto.

The plurality of second driving units 420 can be disposed on a side surface of the substrate 100. Among the four side surfaces of the substrate 100, the side surface of the substrate 100 on which the plurality of second driving units 420 are disposed can be the closest side surface to the plurality of first driving units 420. Further, the plurality of second driving units 420 can be disposed in the same direction as the plurality of lines 200. The plurality of second driving units 420 can be perpendicular to the plurality of lines 200. Further, some areas of the plurality of second driving units 420 can extend in a direction of the lower surface of the substrate 100. For example, some areas of the plurality of second driving units 420 can overlap side surfaces of the substrate 100, and the remaining areas may not overlap side surfaces of the substrate 100. In this case, the plurality of second driving units 420 can face the plurality of first driving units 410.

The plurality of first and second driving units 410 and 420 and the plurality of lines 200 can correspond to each other on a one-to-one basis, and can be electrically connected with each other. For example, one line 200 can be electrically connected with one first driving unit 410 and one second driving unit 420. Further, the number of the plurality of lines 200, the plurality of first driving units 410, and the plurality of second driving units 420 can be the same, but is not limited thereto.

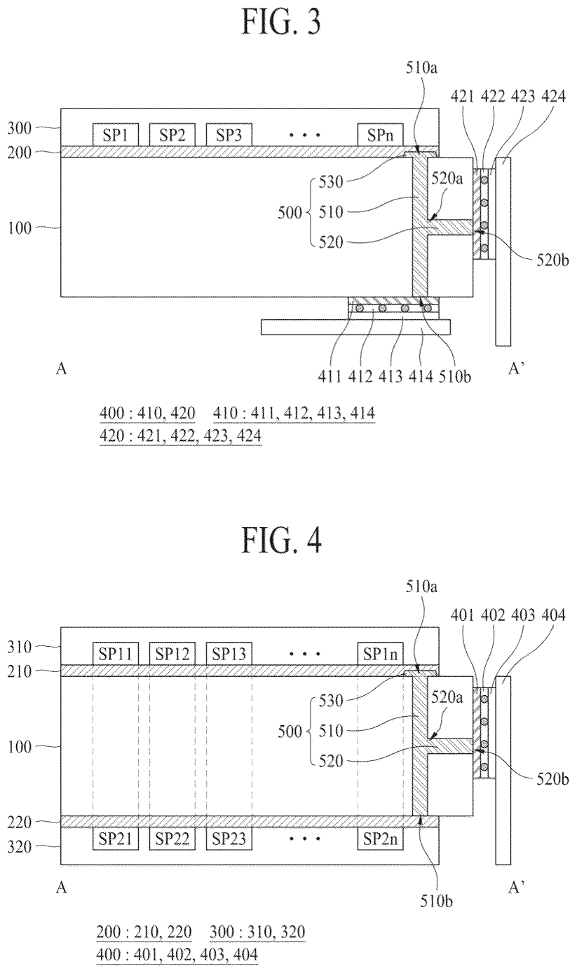

FIG. 3 is a cross-sectional view of the display device 1000 according to a first embodiment of the present disclosure. Specifically, FIG. 3 is a cross-sectional view taken along line A-A′ of FIG. 2.

Referring to FIG. 3, the display device 1000 according to the first embodiment of the present disclosure can include the substrate 100, the plurality of lines 200, a light emitting unit 300, the driving unit 400, and a plurality of connection parts 500.

The substrate 100 can be formed of glass or plastic, but is not limited thereto. The display device according to an embodiment of the present disclosure can be configured in a top emission type in which the emitted light is emitted upward. Therefore, as the material of the substrate 100, not only a transparent material but also an opaque material can be used.

The plurality of lines 200 can be disposed on an upper surface of the substrate 100. The plurality of lines 200 can be spaced apart from each other along one direction. Further, the plurality of lines 200 can be signal lines such as a gate line, a data line, or a common voltage line.

The light emitting unit 300 can be disposed on the plurality of lines 200. The light emitting unit 300 includes a plurality of sub-pixels SP and can emit light. Each sub-pixel SP1 to SPn of the plurality of sub-pixels SP can include a light emitting device and a plurality of driving elements for driving the light emitting device, where n is a natural number such as an integer greater than 1. The light emitting device of each of the plurality of sub-pixels SP can emit any one of red, green, and blue light. The plurality of driving elements of each of the plurality of sub-pixels SP can include a switching thin film transistor and a driving thin film transistor. In addition, the light emitting unit 300 can further include an encapsulation layer for protecting the plurality of sub-pixels SP.

The plurality of lines 200 and the plurality of sub-pixels SP can be electrically connected with each other through contact holes. For example, the plurality of lines 200 can transfer signals to light emitting devices and the plurality of driving elements of the plurality of sub-pixels SP. For example, when the plurality of lines 200 include gate lines, the plurality of lines 200 can transfer signals to gate electrodes of the switching thin film transistor or the driving thin film transistor. Alternatively, when the plurality of lines 200 include the common voltage line, the plurality of lines 200 can transfer signals to electrodes of the light emitting devices.

The driving unit 400 is electrically connected with the plurality of lines 200, and can apply various signals to the plurality of lines 200. As described above, the driving unit 400 can include a plurality of first driving units 410 and a plurality of second driving units 420.

The plurality of first driving units 410 can be disposed on an edge of a lower surface of the substrate 100. The plurality of first driving units 410 can include a first connection electrode 411, a first adhesive layer 412, a first flexible circuit film 413, and a first printed circuit board 414.

The first connection electrode 411 is disposed on the edge of the lower surface of the substrate 100 and can be in contact with the lower surface of the substrate 100. The first connection electrode 411 can include a metallic material such as silver (Ag) or carbon (C), but is not limited thereto.

The first adhesive layer 412 can be disposed on a lower surface of the first connection electrode 411. Further, the first adhesive layer 412 can physically fix the first flexible circuit film 413 on the first connection electrode 411. The first adhesive layer 412 can include an organic material having an adhesiveness. For example, the first adhesive layer 412 can include materials such as vinyl acetate, styrene, ethylene-vinyl acetate, styrene-butadiene, polyester, etc., but is not limited thereto.

The first adhesive layer 412 can include a conductive ball distributed in the organic material. The first connection electrode 411 and the first flexible circuit film 413 can be electrically connected with each other through the conductive ball. The conductive ball can include a metal material such as silver (Ag), copper (Cu), zinc (Zn), indium (In), or the like, but is not limited thereto.

The first flexible circuit film 413 can be disposed on a lower surface of the first adhesive layer 412. For example, the first adhesive layer 412 can be disposed between the first connection electrode 411 and the first flexible circuit film 413. The first flexible circuit film 413 can include a lead wire. The lead wire can be electrically connected with the first connection electrode 411 through the conductive ball of the first adhesive layer 412.

The first printed circuit board 414 can be disposed on a lower surface of the first flexible circuit film 413. For example, the first flexible circuit film 413 can be disposed between the first adhesive layer 412 and the first printed circuit board 414. The first printed circuit board 414 can be electrically connected with the lead wire of the first flexible circuit film 413. For example, the first printed circuit board 414 can apply a signal for driving the plurality of sub-pixels SP through the lead wire of the first flexible circuit film 413. Further, the first printed circuit board 414 can include a timing controller, a power circuit, a memory element or the like.

The plurality of second driving units 420 can be disposed on the side surface of the substrate 100. The plurality of second driving units 420 can include a second connection electrode 421, a second adhesive layer 422, a second flexible circuit film 423, and a second printed circuit board 424. The plurality of second driving units 420 include the same configuration as the plurality of first driving units 410, and thus detailed descriptions thereof will be omitted or may be briefly provided. Further, the plurality of first driving units 410 and the plurality of second driving units 420 can supply the same signal, but are not limited thereto.

The plurality of connection parts 500 can be disposed in the substrate 100 and on the upper surface of the substrate 100. The plurality of connection parts 500 can transfer signals supplied from the driving unit 400 to the plurality of lines 200. Accordingly, the signals supplied from the driving unit 400 can be applied to the plurality of sub-pixels SP. Further, the plurality of connection parts 500 can include a metallic material such as copper (Cu), but are not limited thereto.

Each of the plurality of connection parts 500 can include a first connection part 510, a second connection part 520, and a third connection part 530.

The first connection part 510 can have a column shape penetrating from the upper surface of the substrate 100 to the lower surface of the substrate 100. A first region 510a of the first connection part 510 can be located in the same plane as the upper surface of the substrate 100, and a second region 510b of the first connection part 510 can be located in the same plane as the lower surface of the substrate 100. Further, the first region 510a of the first connection part 510 can be in contact with a lower surface of the third connection part 530, and the second region 510b of the first connection part 510 can be in contact with the first connection electrode 411.

The first and second regions 510a and 510b of the first connection part 510 can overlap each other, but are not limited thereto. The first connection part 510 is formed in a column shape perpendicular to the upper surface of the substrate 100, and the first and second regions 510a and 510b of the first connection part 510 can overlap each other. Alternatively, the first connection part 510 is formed in a column shape forming an acute angle with the upper surface of the substrate 100, so that the first and second regions 510a and 510b of the first connection part 510 may not overlap each other.

The second connection part 520 can have a column shape penetrating a partial region of the substrate 100. A first region 520a of the second connection part 520 can be in contact with a side surface of the first connection part 510, and a second region 520b of the second connection part 520 can be in contact with the second connection electrode 421. Further, the second region 520b of the second connection part 520 can be located in the same plane as the side surface of the substrate 100. Since the first and second connection parts 510 and 520 are made of the same material, regions in which the first and second connection parts 510 and 520 contact with each other may not be distinguished. For example, the second connection part 520 can have a shape protruding from the side surface of the first connection part 510 to the side surface of the substrate 100. Also, the first and second connection parts 510 and 520 can be perpendicular to each other.

The first and second regions 520a and 520b of the second connection part 520 can overlap each other, but are not limited thereto. The second connection unit 520 can be formed in a column shape perpendicular to the side surface of the substrate 100, and the first and second regions 520a and 520b of the second connection unit 520 can overlap each other. Alternatively, the second connection unit 520 can be formed in a column shape forming an acute angle with the side surface of the substrate 100, and the first and second regions 520a and 520b of the second connection unit 520 may not overlap each other.

The third connection part 530 can be disposed on the upper surface of the substrate 100. An area of a lower surface of the third connection part 530 can be larger than an area of the first region 510a of the first connection part 510. Further, a portion of the lower surface of the third connection part 530 can be in contact with the first region 510a of the first connection part 510. Since the first and third connection parts 510 and 530 are made of the same material, areas in which the first and third connection parts 510 and 530 contact with each other may not be distinguished. For example, the third connection part 530 can have a shape protruding from the first region 510a of the first connection part 510. Also, the third connection part 530 can cover a partial area of the upper surface of the substrate 100.

The plurality of lines 200 can be disposed on the third connection part 530. The plurality of lines 200 can cover an entire upper surface of the third connection part 530, but are not limited thereto. The plurality of lines 200 can be in contact with a partial area of the upper surface of the third connection part 530. Since the plurality of lines 200 and the third connection part 530 are made of a metallic material, the plurality of lines 200 and the third connection part 530 can be electrically connected with each other.

Accordingly, the signal supplied from the driving unit 400 can be transferred to the plurality of lines 200 through the connection part 500. Specifically, the signal supplied from the first driving unit 410 can be transferred to the plurality of lines 200 through first and third connection parts 510 and 530. Further, the signal supplied from the second driving unit 420 can be transferred to the plurality of lines 200 through second and third connection parts 520 and 530.

For example, signals supplied from the first and second driving units 410 and 420 can be transferred to the same line 200 through the connection part 500. In this case, by adjusting the timing of signals supplied from the first and second driving units 410 and 420, the display device can be driven at a high frequency.

In addition, when the first and second driving units 410 and 420 supply the same signal, even if any one of the first and second driving units 410 and 420 is not normally driven, the plurality of lines 200 can be normally supplied with the signal. Specifically, even when the first driving unit 410 is not normally driven, the second driving unit 420 can normally supply the signal to the line 200 through the connection part 500. For example, the signal can be normally supplied to the line 200 even if an additional process such as separating the defective driving unit or connecting the auxiliary driving unit is not performed. Accordingly, the display device can be stably driven.

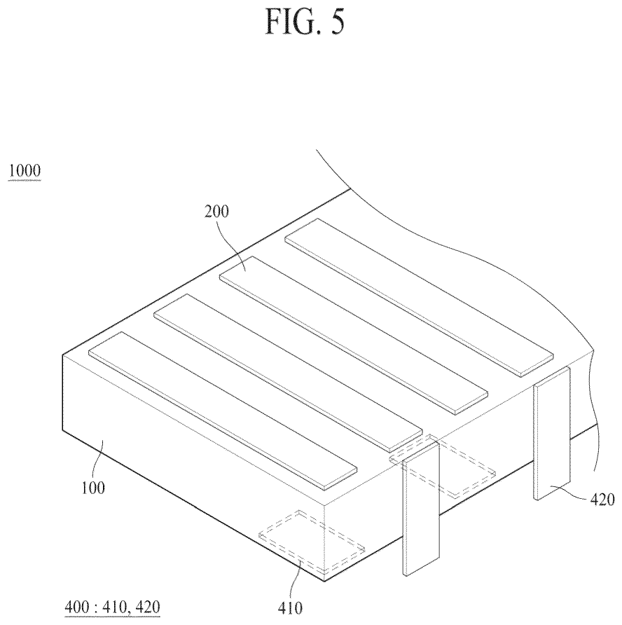

FIG. 4 is a cross-sectional view of a display device 1000 according to a second embodiment of the present disclosure.

Referring to FIG. 4, the display device 1000 according to the second embodiment of the present disclosure can include the substrate 100, the plurality of lines 200, the plurality of light emitting units 300, the driving unit 400, and the plurality of connection parts 500.

The first embodiment illustrated in FIG. 3 discloses driving by the top emission type, but the second embodiment discloses driving by a double-sided emission type. Specifically, in the structure of the first embodiment illustrated in FIG. 3, the plurality of lines 200 and the light emitting unit 300 are disposed only on the upper surface of the substrate 100, but the second embodiment discloses a structure in which the plurality of lines 200 and the light emitting unit 300 are disposed on both the upper surface and the lower surface of the substrate 100.

Referring to FIG. 4, the plurality of lines 200 can include an upper line 210 and a lower line 220. The upper line 210 can be disposed on the upper surface of the substrate 100, and the lower line 220 can be disposed on the lower surface of the substrate 100. The upper and lower lines 210 and 220 can be spaced apart from each other in the same direction. Further, the upper and lower lines 210 and 220 can overlap each other.

The plurality of light emitting units 300 can include an upper light emitting unit 310 and a lower light emitting unit 320. The upper light emitting unit 310 can be disposed on the upper line 210, and the lower light emitting unit 320 can be disposed on the lower line 220. The upper light emitting unit 310 can include an upper sub-pixel group SP1, and the lower light emitting unit 320 can include a lower sub-pixel group SP2. The number of sub-pixels of the upper sub-pixel group SP1 can be equal to the number of sub-pixels of the lower sub-pixel group SP2.

Each sub-pixel SP11 to SP1n of the upper sub-pixel group SP1 can overlap a corresponding one of the sub-pixel SP21 to SP2n of the lower sub-pixel group SP2. In detail, the first sub-pixel SP11 of the upper sub-pixel group SP1 can overlap the first sub-pixel SP21 of the lower sub-pixel group SP2. Likewise, the second sub-pixel SP12 of the upper sub-pixel group SP1 can overlap the second sub-pixel SP22 of the lower sub-pixel group SP2, and so on.

In the upper and lower sub-pixel groups SP1 and SP2, the sub-pixels SP overlapping each other can be driven in the same manner. For example, when the first sub-pixel SP11 of the upper sub-pixel group SP1 emits red light, the first sub-pixel SP21 of the lower sub-pixel group SP2 can also emit red light. Likewise, when the second sub-pixel SP12 of the upper sub-pixel group SP1 emits green light, the second sub-pixel SP22 of the lower sub-pixel group SP2 can also emit green light. For example, images displayed by the first and second light emitting units 310 and 320 are the same as each other, and can overlap with each other based on the substrate 100.

As described above, the plurality of lines 200 and the plurality of sub-pixels SP can be electrically connected with each other through contact holes. For example, the upper line 210 can be electrically connected with the upper sub-pixel group SP1, and the lower line 220 can be electrically connected with the lower sub-pixel group SP2.

The driving unit 400 is electrically connected with the plurality of lines 200, and various signals can be applied to the plurality of lines 200. The driving unit 400 can be disposed on the side surface of the substrate 100. As described above, the driving unit 400 can include a connection electrode 401, an adhesive layer 402, a flexible circuit film 403, and a printed circuit board 404. Since the driving unit 400 disclosed in FIG. 4 includes the same configuration as the second driving unit 420 disclosed in FIG. 3, a detailed description thereof will be omitted or may be briefly mentioned.

The plurality of connection parts 500 can be disposed in the substrate 100 and on the upper surface of the substrate 100. The plurality of connection parts 500 can transfer signals supplied from the driving part 400 to the plurality of lines 200. Each of a plurality of connection parts 500 can include a first connection part, a second connection part and a third connection part 510, 520 and 530.

The first connection part 510 can have a column shape penetrating from the upper surface of the substrate 100 to the lower surface of the substrate 100. A first region 510a of the first connection part 510 can be located in the same plane as the upper surface of the substrate 100, and a second region 510b of the first connection part 510 can be located in the same plane as the lower surface of the substrate 100. Further, the first region 510a of the first connection part 510 can be in contact with a lower surface of the third connection part 530, and the second region 510b of the first connection part 510 can be in contact with the lower line 220.

The second connection portion 520 can have a column shape penetrating a partial region of the substrate 100. A first region 520a of the second connection portion 520 can be in contact with a side surface of the first connection portion 510, and a second region 520b of the second connection part 520 can be in contact with the connection electrode 401.

The third connection part 530 can be disposed on the upper surface of the substrate 100. A portion of a lower surface of the third connection part 530 can be in contact with the first region 510a of the first connection part 510. Further, the upper line 210 can be in contact with the third connection part 530.

Accordingly, the signal supplied from the driving unit 400 can be transferred to the plurality of lines 200 through the connection part 500. In detail, the signal supplied from the driving unit 400 can be transferred to the upper line 210 through first to third connection parts 510 to 530. Further, the signal supplied from the driving unit 400 can be transferred to the lower line 220 through the first and second connection parts 510 and 520. For example, one driving unit 400 can supply the same signal to the upper and lower lines 210 and 220. Accordingly, the upper and lower light emitting units 310 and 320 can display the same image.

Since a transparent display device simply transmits the image displayed from one side of the transparent display device to the other side through a transparent substrate, distortion can occur in the image displayed from the other side of the transparent display device.

On the other hand, the double-sided light emitting display device disclosed in FIG. 4 of the present disclosure displays an image by driving both the upper and lower light emitting units 310 and 320, and thus a stable image can be displayed in both directions of one side and the other side of the display device.

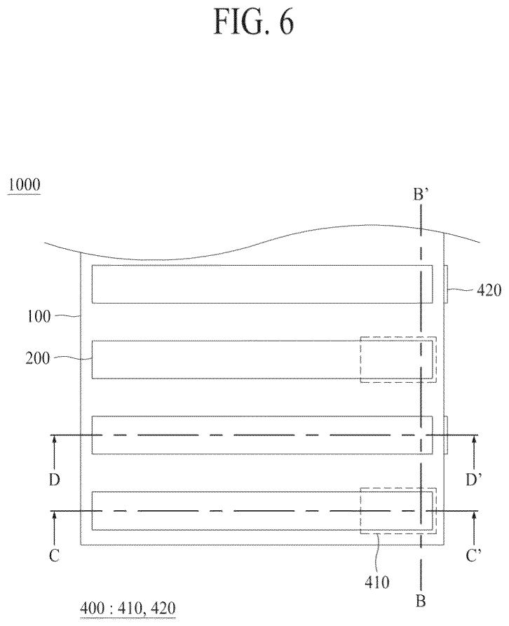

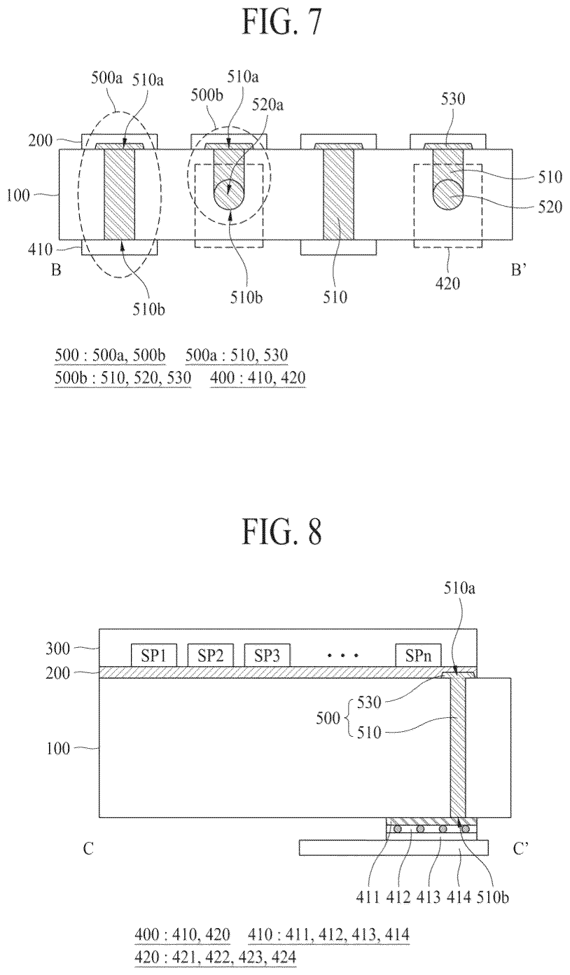

FIG. 5 is a perspective view of the display device 1000 according to the third embodiment of the present disclosure. Further, FIG. 6 is a plan view of the display device 1000 according to the third embodiment of the present disclosure. FIGS. 5 and 6 illustrate a partial area of the display device 1000.

As described above with reference to FIGS. 1 and 2, the display device 1000 according to the third embodiment of the present disclosure can include a substrate 100, a plurality of lines 200, and a driving unit 400.

The driving unit 400 is electrically connected with the plurality of lines 200, and can apply various signals to the plurality of lines 200. Further, the driving unit 400 can include a plurality of first driving units 410 and a plurality of second driving units 420.

In FIGS. 1 and 2, one line 200 is electrically connected with both one first driving unit 410 and one second driving unit 420, but in FIGS. 5 and 6, one line 200 is electrically connected with one of the first driving unit 410 and the second driving unit 420. For example, some of the plurality of lines 200 are connected with the first driving unit 410, are not connected with the second driving unit 420, and the others are connected with the second driving unit 420, and are not connected with the first driving unit 410.

In FIGS. 5 and 6, the line 200 connected with the first driving unit 410 and the line connected with the second driving unit 420 are alternately arranged, but are not limited thereto. Further, the line 200 disposed at an odd number from an end of the substrate 100 is connected with the first driving unit 410, and the line 200 disposed at an even number is connected with the second driving unit 420, but is not limited thereto. Further, the number of the plurality of lines 200 can be equal to the sum of the number of first and second driving units 410 and 420, but is not limited thereto.

Recently, ultra-high-resolution display devices for augmented reality (AR) and virtual reality (VR) have been implemented. Accordingly, since the number of lines is increased while the size of the display device is generally maintained, the distance between adjacent lines can be reduced. In this case, as in the structure of the first embodiment, when the first and second driving units 410 and 420 are arranged to correspond to the plurality of lines 200, the distance between the first driving units 410 and the second driving units 420 adjacent to each other is also reduced.

Accordingly, a connection failure may occur between the driving units adjacent to each other. To address this issue, a third embodiment is provided, which will now be described as follows.

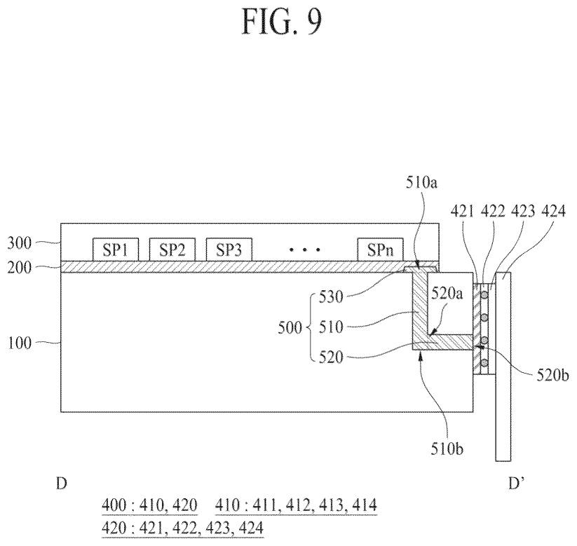

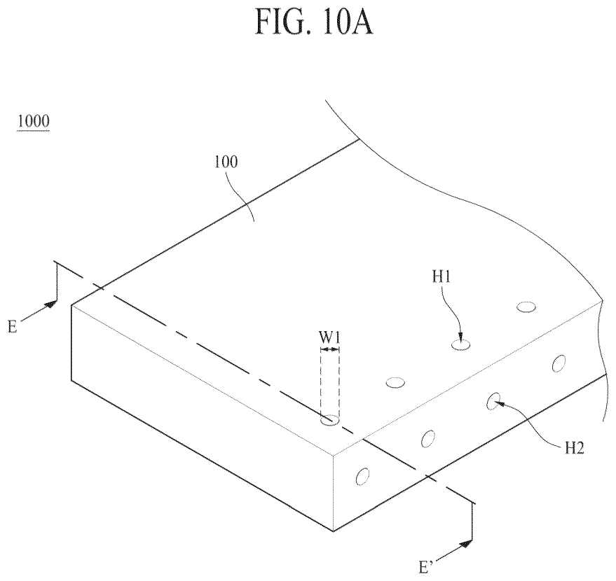

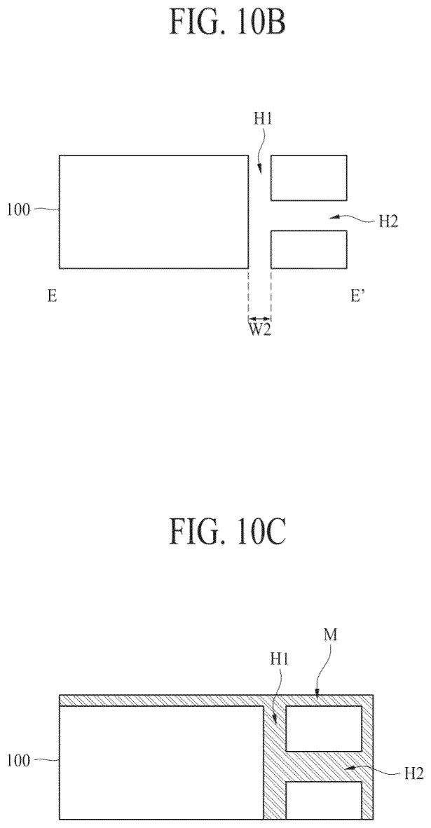

FIG. 7 is a cross-sectional view of the display device 1000 according to a third embodiment of the present disclosure. Specifically, FIG. 7 shows a cross-sectional view taken along line B-B′ of FIG. 6, where a cross-sectional view of the plurality of lines 200, the driving unit 400, and the plurality of connection parts 500 viewed from the side surface of the substrate 100 is illustrated. Further, FIG. 8 is a cross-sectional view of the display device 1000 according to the third embodiment of the present disclosure, and illustrates a cross-sectional view taken along line C-C′ of FIG. 6. Further, FIG. 9 is a cross-sectional view of the display device 1000 according to the third embodiment of the present disclosure, and illustrates a cross-sectional view taken along line D-D′ of FIG. 6.

Referring to FIGS. 7 to 9, structures of the plurality of connecting parts 500 can be different depending on the connection relationship between the plurality of lines 200 and the driving unit 400. Accordingly, the plurality of connecting parts 500 can be divided into a first group 500a and a second group 500b.

Referring to FIGS. 7 and 8, the first group 500a can electrically connect the plurality of lines 200 with the first driving unit 410. Each of the first group 500a can include a first connection part 510 and a third connection part 530.

A first region 510a of the first connection part 510 can be located in the same plane as the upper surface of the substrate 100, and a second region 510b of the first connection part 510 can be located in the same plane as the lower surface of the substrate 100. Further, the first region 510a of the first connection part 510 can be in contact with a lower surface of the third connection part 530, and the second region 510b of the first connection part 510 can be in contact with the first connection electrode 411. Accordingly, some of the plurality of lines 200 can be electrically connected with the first driving unit 410.

Referring to FIGS. 7 and 9, the second group 500b can electrically connect the plurality of lines 200 with the second driving unit 420. Each of the second group 500b can include first to third connection parts 510 to 530.

The first region 510a of the first connection part 510 can be located in the same plane as the upper surface of the substrate 100, and the second region 510b of the first connection part 510 can be located inside the substrate 100. For example, the second region 510b of the first connection part 510 may not be exposed to the outside. Further, the first region 510a of the first connection part 510 can be in contact with a lower surface of the third connection part 530.

The second connection portion 520 can have a column shape penetrating a partial area of the substrate 100. A first region 520a of the second connection portion 520 can be in contact with a side surface of the first connection portion 510, and a second region 520b of the second connection portion 520 can be in contact with the second connection electrode 421. Accordingly, some of the plurality of lines 200 can be electrically connected with the second driving unit 420.

FIGS. 7 and 9 show that the second connection part 520 is disposed at a position adjacent to the second region 510b of the first connection part 510, but the present disclosure is not limited thereto.

As a result, the signal supplied from the first driving unit 410 through the first group 500a of the plurality of connection parts 500 can be transferred to some of the plurality of lines 200. Further, the signal supplied from the second driving unit 420 through the second group 500b of the plurality of connection parts 500 can be transferred to some of the plurality of lines 200.

Accordingly, even if the distance between adjacent lines decreases, it is possible to prevent (or minimize) a connection failure between adjacent driving units 400, and stably connect the plurality of lines 200 with the first and second driving units 410 and 420.

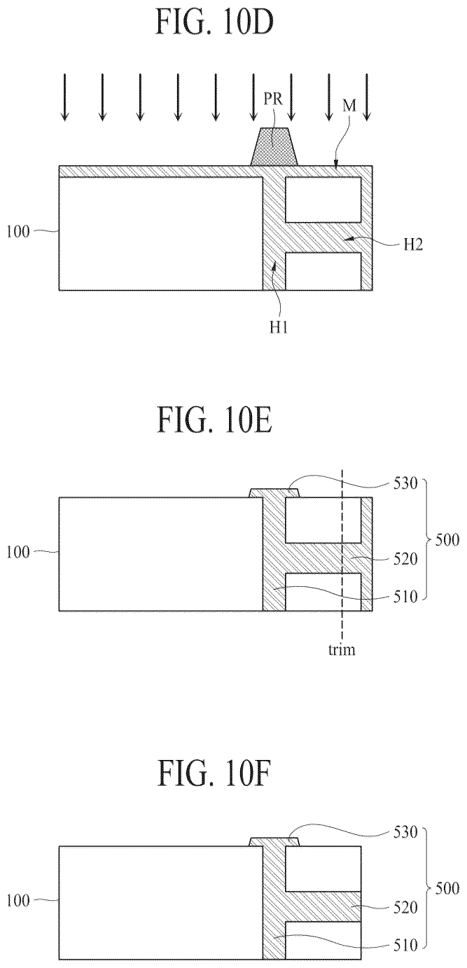

FIGS. 10A to 10F are cross-sectional views illustrating a process of the display device according to the first and second embodiments of the present disclosure. In particular, a process of the plurality of connection parts 500 according to the first and second embodiments of the present disclosure is illustrated.

Referring to FIG. 10A, a first hole H1 and a second hole H2 can be formed in a substrate 100 using a laser. The first hole H1 can be formed to penetrate from an upper surface of the substrate 100 to a lower surface of the substrate 100. Further, the second hole H2 can be formed to reach an area in which the first hole H1 is formed from a side surface of the substrate 100. For example, the first and second holes H1 and H2 can be connected with each other in the substrate 100. A diameter of the cross-sections of the first and second holes H1 and H2 can be a first width W1. Further, in FIG. 10A, the cross-sections of the first and second holes H1 and H2 are circular, but are not limited thereto.

FIG. 10B is a cross-sectional view taken along line E-E′ of FIG. 10A. Referring to FIG. 10B, a size of the first and second holes H1 and H2 can be increased through an etching process. Accordingly, the diameter of the cross-sections of the first and second holes H1 and H2 can be a second width W2 greater than the first width W1.

Referring to FIG. 10C, a metal material M can be plated on the substrate 100 to fill the first and second holes H1 and H2 of the substrate 100. The metal material M can be copper (Cu), but is not limited thereto. The metal material M can cover both an upper surface and a side surface of the substrate 100. Further, an inside of the first and second holes H1 and H2 can be filled with the metal material M. Also, the metal material M can have fluidity so that the metal material M can be filled in the first and second holes H1 and H2 of the substrate 100.

Referring to FIG. 10D, after a photoresist PR is formed on the metal material M plated on the upper surface of the substrate 100, an etching process can be performed. The photoresist PR can be disposed at a position overlapping the first hole H1. Further, an area of a lower surface of the photoresist PR can be larger than an area of the cross section of the first hole H1. For example, the metal material M plated in the first hole H1 may not be etched by the photoresist PR.

By the etching process, the metal material M plated on the upper surface of the substrate 100 can be removed as illustrated in FIG. 10E. Further, the metal material M plated on the area overlapping the photoresist PR can remain plated. For example, the metal material M plated on a partial region of the upper surface of the substrate 100 remains and can cover the upper surface of the first hole H1. Also, since the area of the lower surface of the photoresist PR is larger than the area of the cross section of the first hole H1, an area of a lower surface of a remaining metal material M can also be larger than the area of the cross section of the first hole H1. In this case, the remaining metal material M can function as a third connection part 530 later, and the metal material M filling the inside of the first hole H1 can function as a first connection part 510. For example, an area of a lower surface of the third connection part 530 can be larger than an area of an upper surface of the first connection part 510.

Referring to FIG. 10E, a scribing process can be performed. Specifically, a partial area of the substrate 100 can be removed along a trimming line Trim. Accordingly, the metal material M plated on the side surface of the substrate 100 and an edge area of the substrate 100 can be removed.

Referring to FIG. 10F, the side surface of the substrate 100 can be non-uniform due to the scribing process, and thus a grinding process can be performed. Accordingly, since the side surface of the substrate 100 in which the second hole H2 formed has a uniform surface, a driving unit to be disposed on the side surface of the substrate 100 later can be stably attached. In conclusion, a connection part 500 including first to third connection parts 510 to 530 can be formed.

As mentioned above, FIGS. 10A to 10F illustrate the process of the display device according to the first and second embodiments of the present disclosure, but referring to this, a process of the display device according to the third embodiment can be started. Specifically, the first hole H1 can be formed from the upper surface of the substrate 100 to a specific point of the inside of the substrate 100, and the second hole H2 can be formed from the side surface of the substrate 100 to the area in which the first hole H1 is formed. Thereafter, the metal material M can be plated to fill the first and second holes H1 and H2 of the substrate 100.

According to the present disclosure, the following advantageous effects can be obtained.

According to the present disclosure, the plurality of light conversion layers can be formed so that light efficiency can be improved, and reflectance due to external light can be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a line disposed on an upper surface of a substrate;
a driving unit disposed on a side surface of the substrate; and
a connection part disposed in the substrate,
wherein the connection part includes a first connection part penetrating from the upper surface of the substrate to a lower surface of the substrate, and a second connection part protruding from the first connection part to the side surface of the substrate, and
the second connection part is in contact with the driving unit to be electrically connected with the driving unit at the side surface of the substrate.

2. The display device of claim 1, wherein the first connection part includes:
a first region located in a same plane as the upper surface of the substrate, and
a second region located in a same plane as the lower surface of the substrate.

3. The display device of claim 2, wherein the connection part includes a third connection part disposed on the upper surface of the substrate,
the third connection part is in contact with the first region of the first connection part, and
the line is in contact with the third connection part.

4. The display device of claim 3, wherein an area of a lower surface of the third connection part is larger than an area of the first region of the first connection part.

5. The display device of claim 2, wherein the driving unit includes a first driving unit disposed on the lower surface of the substrate and a second driving unit disposed on the side surface of the substrate,
the first connection part is in contact with the first driving unit, and
the second connection part is in contact with the second driving unit.

6. The display device of claim 5, wherein the line is electrically connected with both the first and second driving units.

7. The display device of claim 3, wherein the line includes an upper line disposed on the upper surface of the substrate and a lower line disposed on the lower surface of the substrate,
the upper line is in contact with the third connection part, and
the lower line is in contact with the second region of the first connection part.

8. The display device of claim 7, wherein the driving unit is electrically connected with both the upper line and the lower line.

9. The display device of claim 7, further comprising:
an upper sub-pixel group composed of sub-pixels and disposed on the upper line; and
a lower sub-pixel group composed of sub-pixels and disposed on the lower line,
wherein each sub-pixel of the upper sub-pixel group and one sub-pixel of the lower sub-pixel group overlap each other.

10. The display device of claim 9, wherein when a first sub-pixel of the upper sub-pixel group and a second sub-pixel of the lower sub-pixel group overlap each other, and
the first and second sub-pixels emit lights with a same color.

11. A display device comprising:
a plurality of lines disposed on an upper surface of a substrate;
a first driving unit disposed on a lower surface of the substrate;
a second driving unit disposed on a side surface of the substrate; and
a connection part disposed in the substrate,
wherein each of the plurality of lines is electrically connected with one of the first and second driving units and is not electrically connected with the other of the first and second driving units by the connection part.

12. The display device of claim 11, wherein the connection part includes a first group and a second group, the first group and the second group having different shapes from each other, and
some of the plurality of lines are electrically connected with the first driving unit through the first group, and the others of the plurality of lines are electrically connected with the second driving unit through the second group.

13. The display device of claim 12, wherein the first group includes a first connection part penetrating from an upper surface of the substrate to the lower surface of the substrate, and
at the lower surface of the substrate, the first connection part and the first driving unit are in contact with each other.

14. The display device of claim 12, wherein the second group includes a first connection part and a second connection part, both the first and second connection parts penetrating a partial area of the substrate,
the first connection part includes a first region located in a same plane as the upper surface of the substrate and a second region disposed in the substrate,
the second connection part protrudes from the first connection part to the side surface of the substrate, and
on the side surface of the substrate, the second connection part and the second driving unit are in contact with each other.

15. The display device of claim 12, wherein the line electrically connected with the first driving unit and the line electrically connected with the second driving unit are alternately arranged.

16. The display device of claim 12, wherein the line electrically connected with the first driving unit overlaps the first driving unit, and
the line electrically connected with the second driving unit does not overlap the first driving unit.
